(19) United States
(12) Patent Application Publication
(10) Pub. No.: US 2025/0031463 A1
(43) Pub. Date: Jan. 23, 2025

(54) FLEXIBLE AND MINIATURIZED COMPACT VERTICAL COLOR SENSOR

(71) Applicant: Georgia State University Research Foundation, Inc., Atlanta, GA (US)

(72) Inventors: Sidong Lei, Atlanta, GA (US); Ningxin Li, Atlanta, GA (US); Aisha Okmi, Atlanta, GA (US)

(21) Appl. No.: 18/714,464

(22) PCT Filed: Nov. 30, 2022
(86) PCT No.: PCT/US2022/080657

§ 371 Date: May 29, 2024

Related U.S. Application Data
(60) Provisional application No. 63/284,451, filed on Nov. 30, 2021.

(51) Int. Cl. H01L 27/146; H01L 31/0272; H01L 31/032; H01L 31/101

(52) U.S. Cl. CPC H01L 27/14647; H01L 31/0272; H01L 31/0322; H01L 31/1013

(57) ABSTRACT

Various examples are provided related to color and optical sensing with vertically stacked sensors. In one example, a vertical color sensing element includes a R-sensing channel layer including a first sensing material, G-sensing channel layer including a second sensing material, and a B-sensing channel layer including a third sensing material. First and second transparent insulating layer having first and second thicknesses are between the R and G sensing channel layers and the G and B sensing channel layers, respectively. The first and second thicknesses can be based upon focal lengths of R-light, G-light and B-light entering the vertical color sensing device. In another example, a vertical optical sensor can include a first sensing channel layer including a first sensing material, a transparent insulating layer, and a second sensing channel layer including a second sensing material. The first sensing material can be vdW-S and the second sensing material can be different.

### CROSS REFERENCE TO RELATED APPLICATIONS

This application claims priority to, and the benefit of, U.S. provisional application entitled “Flexible and Miniaturized Compact Vertical Color Sensor” having Ser. No. 63/284,451, filed Nov. 30, 2021, which is hereby incorporated by reference in its entirety.

### BACKGROUND

Color sensing plays an essential role in the visual inspection of lesions and tissues, measurement of blood oxygen level, plant health monitoring in ecological research, and many other applications in medical care and environmental surveillance. The fundamental principle of color sensing is to construct optoelectronic devices that mimic the human eye's color perception structures to detect the incident light color from the portion of the red, green, and blue (RGB) components. Thus, each color sensor typically consists of three independently working channels in response to each of these components.

### SUMMARY

Aspects of the present disclosure are related to color and optical sensing with vertically stacked sensors. In one aspect, among others, a vertical color sensing element comprises a R-sensing channel layer comprising a first sensing material; a first transparent insulating layer disposed on a side of the R-sensing channel layer, the first transparent insulating layer having a first thickness; a G-sensing channel layer comprising a second sensing material, the G-sensing channel layer disposed on a side of the first insulating transparent layer opposite the R-sensing channel layer; a second transparent insulating layer disposed on a side of the G-sensing channel layer opposite the first transparent insulating layer, the second transparent insulation layer having a second thickness; and a B-sensing channel layer comprising a third sensing material, the B-sensing channel layer disposed on a side of the second transparent insulating layer opposite the G-sensing channel layer.

In one or more aspects, the first and second thicknesses can be based upon focal lengths of R-light, G-light and B-light entering the vertical color sensing device. The focal lengths can be associated with a lens directing the R-light, G-light and B-light into the vertical color sensing device. The vertical color sensing element can have a geometry conforming to a field curvature generated by the lens. The vertical color sensing element can comprise a UV-sensing layer or an IR-sensing layer. The UV-sensing layer can be separated from the B-sensing channel layer by another transparent insulating layer. The IR-sensing layer can be separated from the R-sensing channel layer by another transparent insulating layer. The first transparent insulating layer can comprise magnesium fluoride (MgF₂) or mica. The second transparent insulating layer can comprise magnesium fluoride (MgF₂) or mica.

In various aspects, one or more of the first, second and third sensing materials can be van der Waal semiconductors (vdW-Ss). Thickness of the first, second or third sensing material can be based upon sensitivity of that sensing material. The first sensing material can comprise copper indium selenide (CIS). The second sensing material can comprise indium selenide (InSe). The third sensing material can comprise gallium sulfide (GaS). The first, second and third sensing materials can comprise a series of a van der Waal semiconductor (vdW-S). The vdW-S can be GaSe₁₋ₓSₓ, InGa₁₋ₓSeₓ, InGa₁₋ₓSeₓTe, TexSe₁₋ₓ, GaₓIn₁₋ₓSe, GaSₓSe₁₋ₓ, MoSₓSe₁₋ₓ, or MoₓW₁₋ₓSe₂, where 0≤x≤1 with each of the first, second and third sensing materials tuned to a different bandgap.

In another aspect, a vertical sensing device can comprise an array of vertical color sensing elements. The vertical color sensing elements can include features as described above. The array of vertical color sensing elements can be formed on a curved device holder. Curvature of the curved device holder can conform to a field curvature generated by a lens that directs light into the array of vertical color sensing elements. The array of vertical color sensing elements can be formed on a flexible substrate.

In another aspect, a vertical optical sensor can comprise a first sensing channel layer comprising a first sensing material comprising a van der Waal semiconductor (vdW-S); a transparent insulating layer disposed on a side of the first sensing channel layer, the first transparent insulating layer having a thickness; and a second sensing channel layer comprising a second sensing material, the second sensing channel layer disposed on a side of the insulating transparent layer opposite the first sensing channel layer. The first sensing material can exhibit a first photoresponse spectral range and the second sensing material can exhibit a second photoresponse spectral range different than the first photoresponse spectral range. The second sensing channel can be a UV-sensing layer or an IR-sensing layer. In one or more aspects, the vdW-S can be a III-VI group semiconductor, a III-V group compound, or a transition metal chalcogenide. The first material can comprise a vdW—S alloy having a first composition of elements tuned to a first bandgap and the second sensing material comprises the vdW—S alloy having a second composition of elements tuned to a second bandgap. The vdW—S alloy can be GaSe₁₋ₓSₓ, InGa₁₋ₓSeₓ, InGa₁₋ₓSeₓTe, TexSe₁₋ₓ, GaₓIn₁₋ₓSe, GaSₓSe₁₋ₓ, MoSₓSe₁₋ₓ, or MoₓW₁₋ₓSe₂, where 0≤x≤1 with each of the first and second sensing materials tuned to different bandgaps. In various aspects, the vertical optical sensor can comprise a second transparent insulating layer disposed on a side of the second sensing channel layer opposite the first transparent insulating layer, the second transparent insulation layer having a second thickness; and a third sensing channel layer comprising a third sensing material, the third sensing channel layer disposed on a side of the second transparent insulating layer opposite the second sensing channel layer. The first material can comprise a vdW—S alloy having a first composition of elements tuned to a first bandgap, the second sensing material can comprise the vdW—S alloy having a second composition of elements tuned to a second bandgap, and the third sensing material can comprise the vdW—S alloy having a third composition of elements tuned to a second bandgap.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described embodiments are usable in all aspects of the disclosure taught herein. Furthermore, the individual features of the dependent claims, as well as all optional and preferred features and modifications of the described embodiments are combinable and interchangeable with one another.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1A illustrates an example of a conventional lateral pixel matrix coated with Bayer color filters, which defines the R-, G-, and B-sensing channels.

FIG. 1B is a schematic diagram illustrating an example of a vdW—S-based vertical color sensor composed of CIS, InSe, and GaS layers serving as the R-, G-, and B-channels, respectively, in accordance with various embodiments of the present disclosure.

FIGS. 1C-1E illustrate the color sensing principles, in accordance with various embodiments of the present disclosure.

FIG. 2A illustrates the large bandgap of GaS which can serve as the B-sensing channel, in accordance with various embodiments of the present disclosure.

FIG. 2B illustrates the valence band and bandgap of InSe which can serve as the G-sensing channel, in accordance with various embodiments of the present disclosure.

FIG. 2C illustrates photoresponse spectra and bandgap of CIS which can serve as the R-sensing channel, in accordance with various embodiments of the present disclosure.

FIG. 2D illustrates an example of color sensor device fabrication, in accordance with various embodiments of the present disclosure.

FIGS. 2E and 2F illustrate examples of normalized photoresponsivity (P. R.) spectra and photocurrent-light intensity curves of the sensing channels, in accordance with various embodiments of the present disclosure.

FIGS. 2G-2I illustrate examples of photocurrent and dark current curves of the RGB sensing channels, in accordance with various embodiments of the present disclosure.

FIG. 3A illustrates an example of an experimental setup for color temperature measurement, in accordance with various embodiments of the present disclosure.

FIG. 3B illustrates examples of raw values sensed by the RGB sensing channels and the corrected tristimulus values, in accordance with various embodiments of the present disclosure.

FIGS. 3C and 3D are a CIE color space chart illustrating the experimentally measured color coordinates and emission spectra with color temperatures, in accordance with various embodiments of the present disclosure.

FIG. 4A is a circuit diagram illustrates an example of a three-pixel color sensor array, in accordance with various embodiments of the present disclosure.

FIG. 4B illustrates an example of color sensor device fabrication, in accordance with various embodiments of the present disclosure.

FIG. 4C is a fake-color scanning electron microscopic (SEM) image of a three-pixel vdW—S-based vertical color, in accordance with various embodiments of the present disclosure.

FIG. 4D is an optical image of an experiential configuration for spatially resolved light intensity mapping and color sensing, in accordance with various embodiments of the present disclosure.

FIG. 4E illustrates an example of detection of light intensity distribution, in accordance with various embodiments of the present disclosure.

FIG. 4F illustrates an example of a RGB light color recognition test on the three-pixel color sensor array, in accordance with various embodiments of the present disclosure.

FIGS. 4G and 4H illustrate the design principle of a vdW—S-based vertical color sensor for chromatic aberration correction and an SEM image of a cross-section of a fabricated vertical color sensor, in accordance with various embodiments of the present disclosure.

FIGS. 41 and 4J are images illustrating a concave device holder and a color sensor formed on a curved device holder, in accordance with various embodiments of the present disclosure.

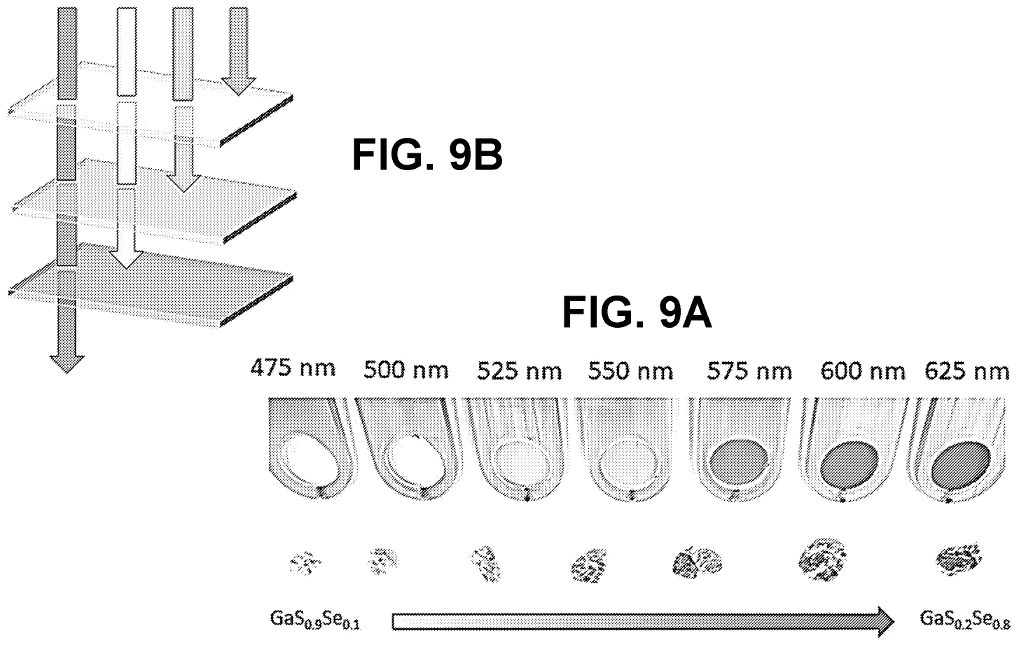

FIGS. 5A-5C illustrate an example of a photoresponsivity spectrum of CIS before and after calibration, in accordance with various embodiments of the present disclosure.

FIGS. 6A and 6B illustrate examples of thickness-dependent photoresponsivity spectra of CIS, in accordance with various embodiments of the present disclosure.

FIGS. 7A-7C illustrate examples of thickness profiles of CIS (R-channel), InSe (G-channel), and GaS (B-channel) layers, in accordance with various embodiments of the present disclosure.

FIG. 8 illustrates an example of a graph of color matching function, in accordance with various embodiments of the present disclosure.

FIGS. 9A and 9B illustrate an example of a single-pixel spectrometer comprising layers including a series of vdW—S alloy with varying bandgaps, in accordance with various embodiments of the present disclosure.

### DETAILED DESCRIPTION

Disclosed herein are various examples related to color and optical sensing with vertically stacked sensors. An image sensor can include a vertical color sensing architecture comprising multiple layers of transparent semiconductor films. The films can include, but not are not limited to, van der Waals semiconductors, perovskite films, organic semiconductor films, etc. As an example of visible image capturing, three layers of such semiconductor films can be stacked vertically to sense red, green and blue light, respectively. Adjacent semiconductor layers are separated with transparent insulting materials. By adding additional semiconductor and insulating layers, the sensing spectral range can further be extended to include infrared and/or ultraviolet ranges. In some embodiments, the sensor can be configured for monochromatic imaging with alternate sensing layers. Reference will now be made in detail to the description of the embodiments as illustrated in the drawings, wherein like reference numbers indicate like parts throughout the several views.

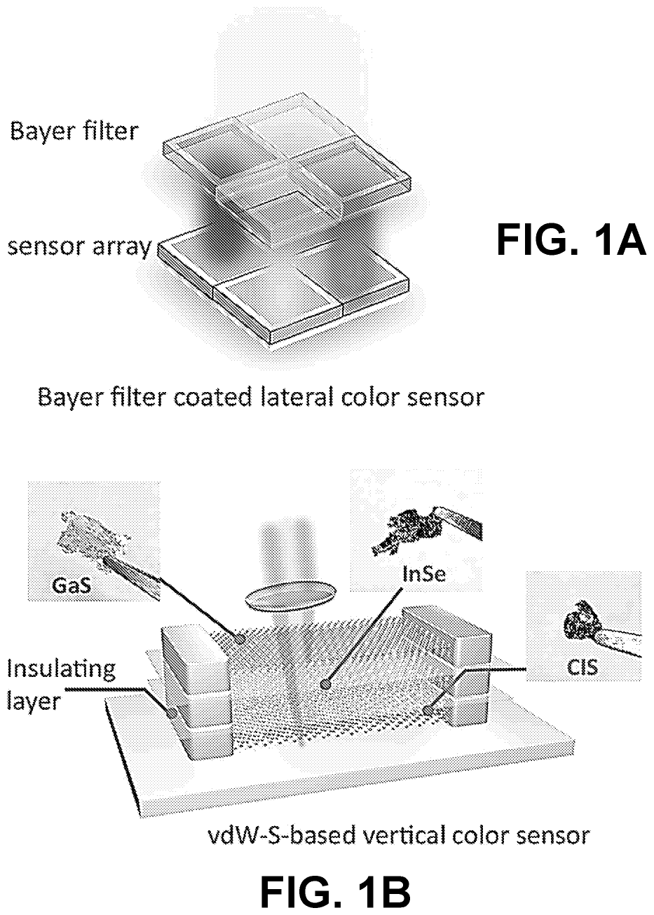

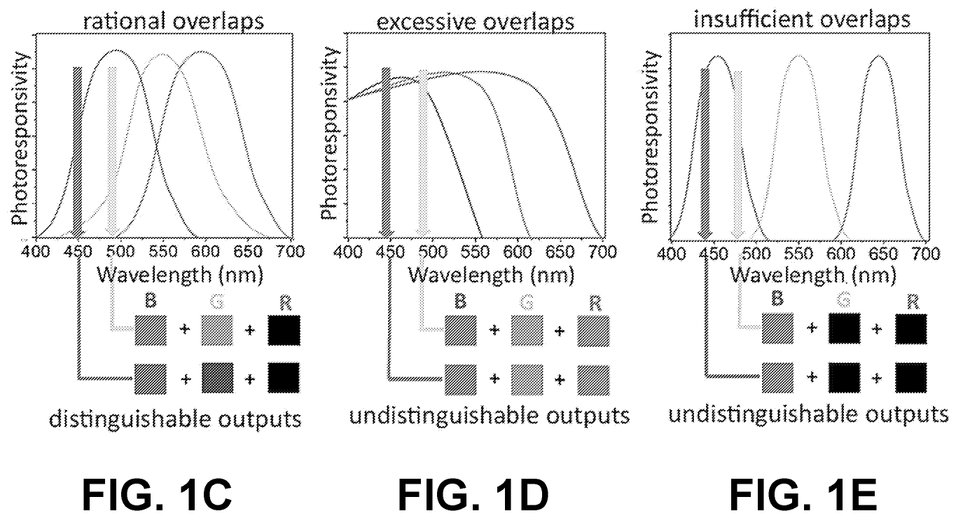

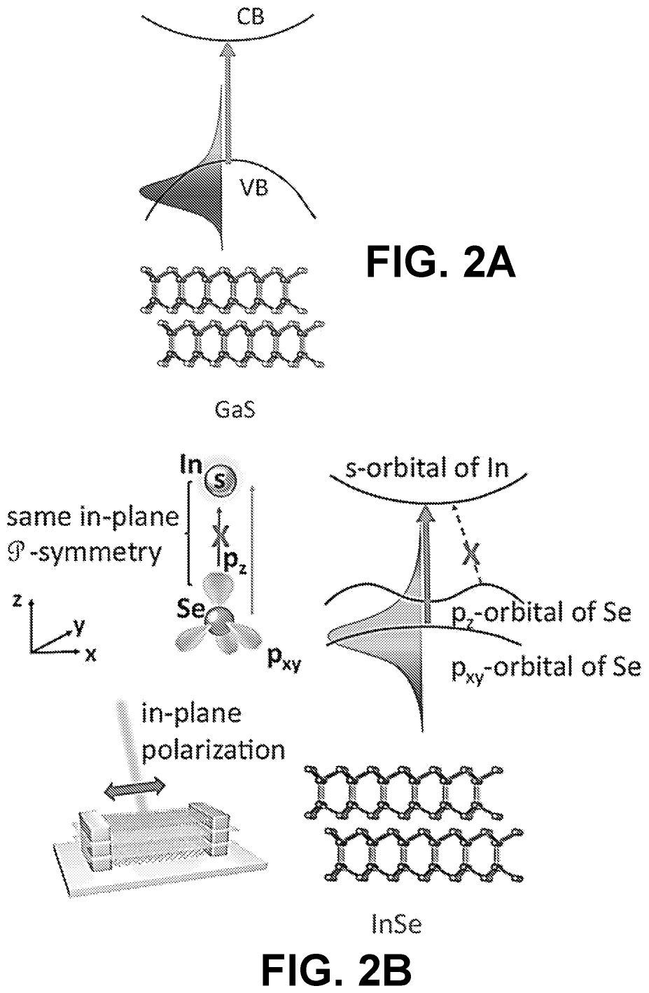

Limited by the availability of conventional semiconductors and the prevailing planar device fabrication technology, the red, green, and blue (RGB) channels are typically constructed out of a lateral array of identical photodetectors with color filters on the top for color component separation. One example of this class of lateral sensors is a silicon photodetector array coated with a Bayer color filter. FIG. 1A illustrates an example of a conventional lateral pixel matrix coated with Bayer color filters, which defines the R-, G-, and B-sensing channels. Despite its wide and mature applications, a Bayer sensor requires at least four side-by-side detectors (two for the G-channel) to accomplish the color recognition function collaboratively, thus occupying extra physical space. This becomes a major obstacle for device miniaturization, particularly when millions of these structures are integrated into image sensors, i.e., the kennel of cameras. To address this issue, Foveon sensors were developed with a vertical color sensing configuration, leveraging the wavelength-dependent penetration depth of light in silicon. Nevertheless, its RGB channels have significant overlaps in photoresponse spectra, making the Foveon sensors less accurate than the Bayer structure in distinguishing the color components.

The development of van der Waal semiconductors (vdW-Ss) and stacking techniques present an alternative approach to overcome the above dilemma by inspiring new hardware architectures. In comparison with the conventional semiconductors, vdW-Ss exhibit rich selections and widely tuning band structures, and as such enable the employment of the optimal materials to detect the R-, G-, and B-light, respectively, without needing additional color filters. Other materials that can be used include, e.g., perovskite films, organic semiconductor films, etc. Further, the continuously improved stacking techniques allow fabrication of complex vertical optoelectronic architectures without worrying about the challenges encountered in conventional semiconductor heterostructures, for example, the lattice mismatch.

Considering these unique benefits, a novel vertical and compact color sensor is disclosed. The sensor can be empowered by the stacking of layered sensing materials (e.g., CuIn₇Se₁₁, InSe, and GaS) to serve as the R-, G-, and B-channels, as illustrated in the example of FIG. 1B. The optical images of FIG. 1B show the raw vdW-S crystals employed in fabrication of a sensing device. The as-fabricated sensor exhibits high accuracy in color sensing, as well as a compact device volume. The color sensing function has been implemented in vdW-S optoelectronics via elaborate material selection and precise energy band structure manipulation. The scalable integration of this type of newly developed sensors can potentially deliver miniature image capture devices and cameras compatible with micro-robotics for biological, medical, and environmental applications. To demonstrate the potential of scalable fabrication, a three-pixel vertical color sensor array has also been constructed with the function of chromatic aberration correction, which can, in turn, simplify the design of optical lenses and accelerate the down-scale of cameras.

To implement the stacking vdW-S color sensor, the proper candidates are first selected out of the abundant material database according to the color sensing principle introduced by the International Commission of Illumination (CIE). The sensing materials can include vdW-S compounds and their alloys that cover the desired optical response spectral range. For example, the sensing materials can include III-VI group semiconductors (e.g., InTe, InSe, GaSe, GaS, GaTe, InCuSe, and their alloys, for example, in forms of InTeₓSe₁₋ₓ, GaₓIn₁₋ₓSe, GaSₓSe₁₋ₓ, etc.), include III-V group vdW-S compounds (e.g., boron nitride (BN), carbon boron nitride (CBN), etc.), or transition metal chalcogenides (e.g., MoS₂, MoSe₂, MoTe₂, WS₂, WSe₂, WTe₂, NbSe₂, TiS₂, etc. and their alloys, such as MoSₓSe₁₋ₓ, MoₓW₁₋ₓSe₂, etc.). The sensing materials can also include organic semiconductor think film or organic perovskite thin film. FIGS. 1C-1E illustrates the color sensing principle. Basically, a color sensor comprises three channels having their respective maximum photoresponse locating at the

R-, G-, and B-light range, meanwhile presenting rational spectral overlaps, as illustrated in FIG. 1C. In this configuration, all sensing channels respond to incident light and generate the corresponding responses (e.g., photocurrents), the ratio of which turns out to be the measurement of color. In contrast, extreme scenarios of either excessive or insufficient overlap will result in color recognition errors because the output ratio among the RGB channels in such cases cannot effectively distinguish the variation in light colors, as explained in FIGS. 1D and 1E. Rational spectral overlaps as shown in FIG. 1C enable color recognition based on the ratio of the RGB channel outputs, whereas excessive overlap as shown in FIG. 1D or insufficient overlap as shown in FIG. 1E leads to undistinguishable outputs, and consequently, color sensing errors.

The excessive overlap is actually one major problem of the silicon-based Foevon sensors, since the small bandgap makes them equally sensitive to the R-, G-, and B-light. On the other hand, the wavelength-dependent penetration depths cannot effectively separate these components, anyway. A similar challenge may also exist in vdW-Ss, especially the R-sensing material, whose smaller bandgap may result in a strong G- and B-light response, and consequently, excessive overlaps. The G-sensing material can bring the same concern. Thus, the first step towards the realization of the vdW-S color sensors is to identify the material candidates with relatively narrow photoresponse spectra primarily distributing in the R-, G-, and B-ranges, but still having rational overlaps.

By adding additional semiconductor and insulating layers, the sensing spectral range can further be extended to include infrared (IR) and/or ultraviolet (UV) sensing. A UV sensing layer can be formed as the top most sensing layer (e.g., disposed over the B-sensing layer because UV is wavelength shorter than the visible blue range), and an IR sensing layer can be the lowest sensing layer (e.g., disposed under the R-sensing layer because the IR wavelength is longer than the visible red). For example, a device can include (from bottom to top) an IR-sensing layer, an R-sensing layer, a G-sensing layer, a B-sensing layer, and an UV-sensing layer. Between the sensing layers, a transparent insulating layer can be formed to avoid the short circuit and interference. Materials exhibiting a photoresponse to UV/IR light can be used for UV or IR sensing including, e.g., boron nitride for UV sensing or CuInSe for IR sensing by tunable bandgap.

### Example

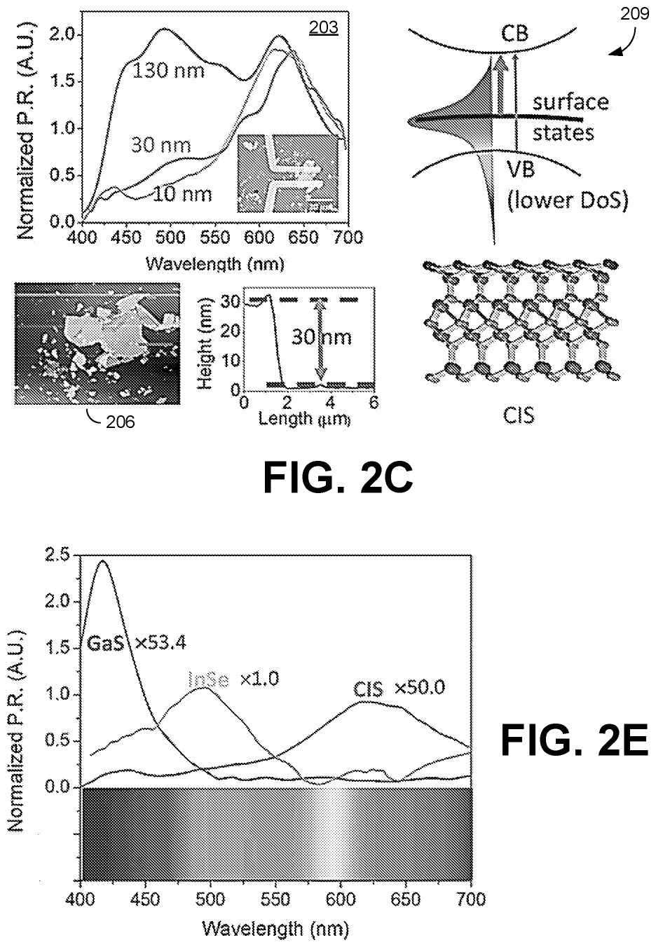

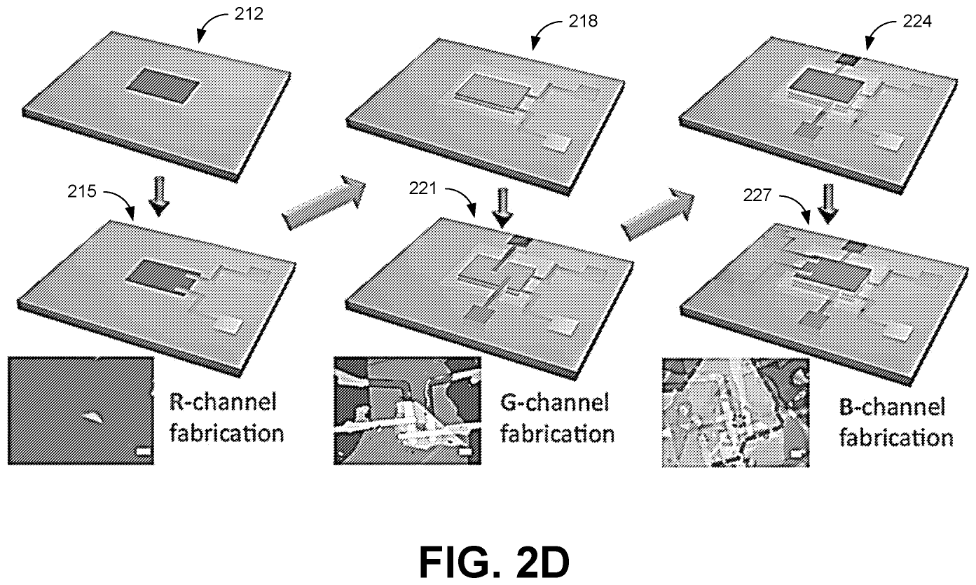

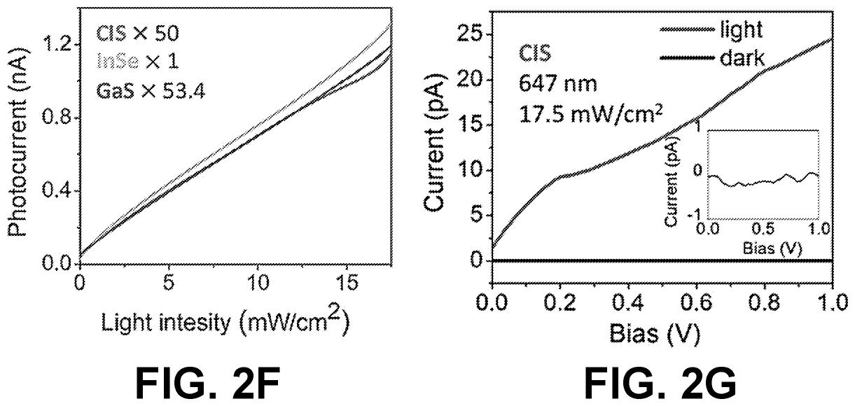

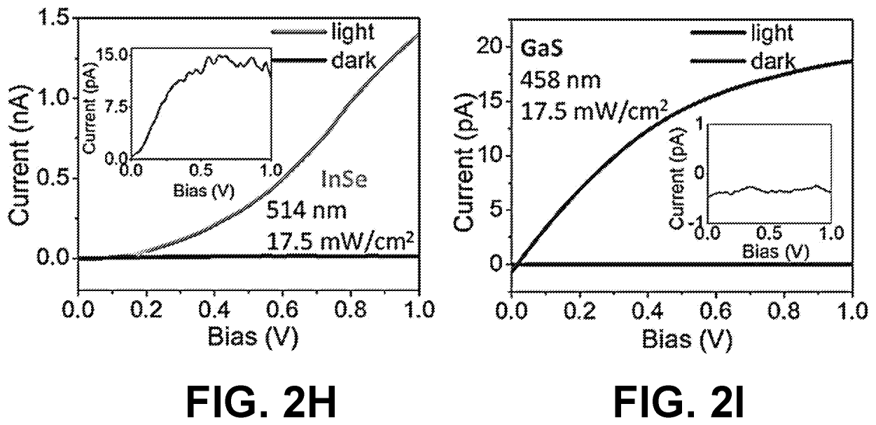

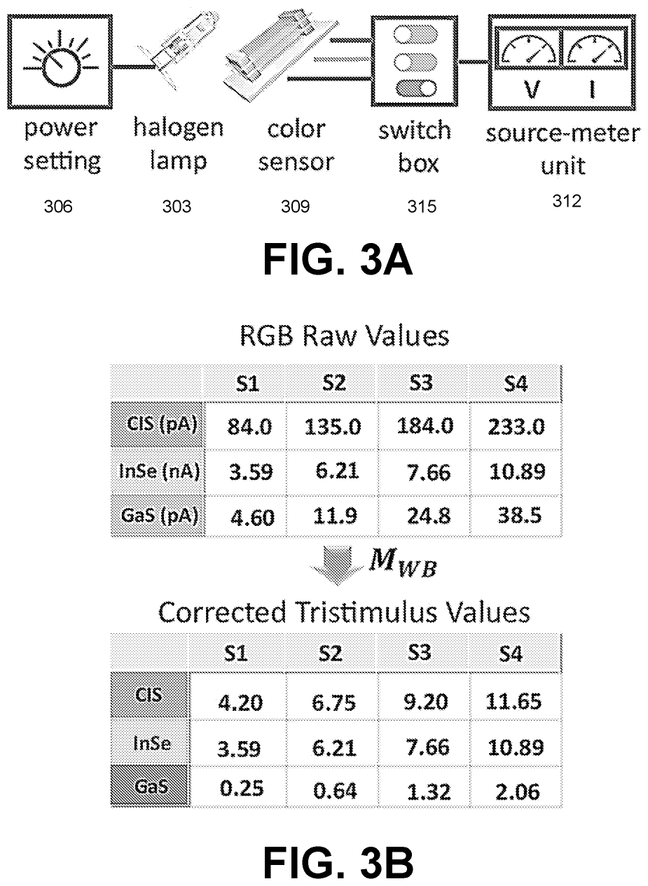

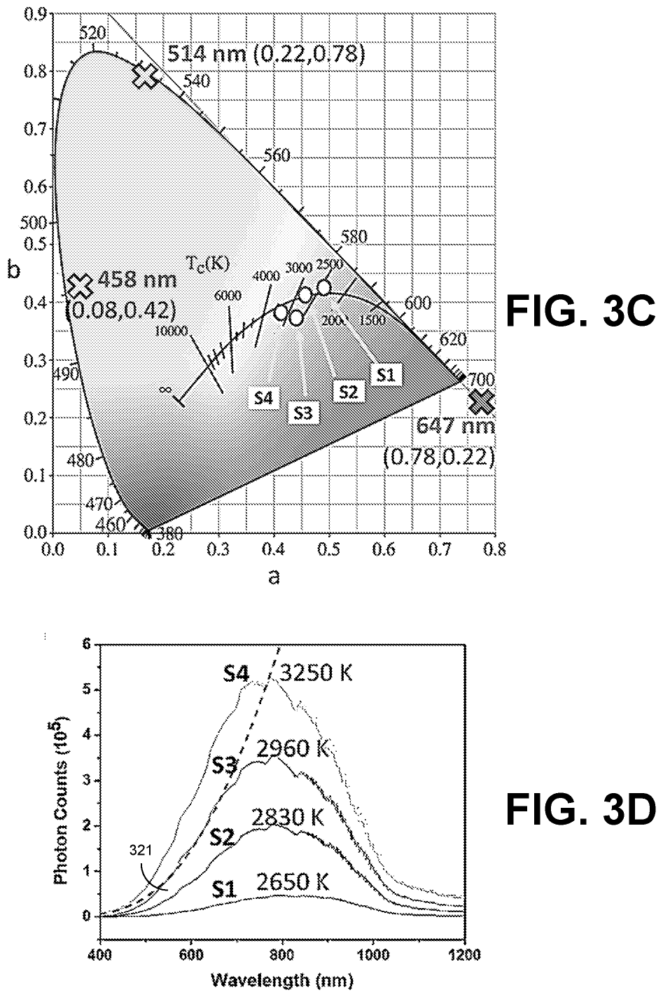

For the B-channel, GaS (˜25 nm thickness) was chosen due to its relatively large (or wide) bandgap, as illustrated in FIG. 2A. Meanwhile, few-layered InSe was employed as the G-sensing material due to its unique and intriguing band structure that delivers an elegant solution to the spectral overlap. InSe belongs to the III-VI layered materials showing direct-to-indirect band structure transition with a decreasing thickness. Specifically, investigations have indicated that few-layered InSe has an indirect bandgap with the valence band mainly composed of the p_{z}-orbitals of selenium anions, as illustrated in FIG. 2B. InSe has its valence band (VB) composed of p_{z}- and p_{xy}-orbitals, which can be cataloged by their symmetry. The p_{z}-orbital shares the same in-plane parity with the conduction band (CB). Although these p_{z}-orbitals primarily determine the bandgap of few-layered InSe, the inter-band dipolar transition from them to the conduction band (s-orbitals of indium cations) is forbidden in a normal light incidence configuration (in-plane polarization), as shown in FIG. 2B, which was used in the device. This is because the Se p_{z}-orbitals and the In s-orbital share the same in-plane parity symmetry (P-symmetry) that disables the dipolar excitation with horizontal polarization. This ineffective inter-band transition creates a long spectra tail extending to the R-light, as illustrated in FIG. 2E. On the other hand, the very flat dispersion of the p_{xy}-band causes a singularity in the density of states (DoS) and creates its photoresponse strongest to G-light but less effective to B-light.

Compared with the G- and B-sensing channels, searching for R-sensing vdW-S turned out to be challenging to identify a III-VI material to reproduce the above delicate band structure but with a narrower bandgap. On the other hand, other groups of vdW-Ss, such as MoS₂, with a strong R-light excitation, usually have a broad photoresponse in the B- and G-regions, repeating the aforementioned problem of excessive spectral overlapping. Fortunately, it was discovered that layered CIS, an emerging ternary vdW-S has a stronger photoresponse in the range of 600 to 700 nm as well as a thickness-controllable sensitivity in the G- and B-regions, making it an ideal R-sensing candidate. To find the desired device fabrication parameter, a series of CIS samples with various thicknesses were mechanically exfoliated from the bulk crystal (shown in FIG. 1B) and their photoresponse spectra (P.R.) were collected, as shown in FIG. 2C (left panel 203). The spectra were calculated with the equation of R(λ)=[I_{light}(λ)−I_{dark}]/P(λ), where I_{light} and I_{dark} are the photocurrent and dark current measured with a 1 V bias voltage. P(λ) denotes the incident light.

FIG. 2C also shows the optical and AFM images (206) of a 30 nm-thick device employed during this test. The profile measurement was performed along the solid lines in AFM mapping image (206). Out of these measurements, an intriguing phenomenon emerges that, the photocurrent levels in the G- and B-regions decrease as the CIS becomes thinner, while the R-light region (600˜700 nm) remains strong. This abnormal behavior distinguishes CIS from other vdW-Ss, including the aforementioned III-VI materials and transition metal dichalcogenides (TMDCs) that experience blue shifting in photoresponse peaks as the materials becomes thinner. The current experimental observation provides an outline of the electron structure variation, as illustrated in FIG. 2C. The right panel 209 shows a speculated energy band structure of CIS. The VB has a lower DoS as the sample becomes thinner, whereas the DoS of the surface states does significantly depend on the thickness and produces a dominating photoresponse to R-light. The R-light and G-/B-light response originate from two distinct photoexcitation and transitions in CIS. As the sample thickness reduces, the DoS corresponding to the G-/B-light excitation drops more rapidly than that of R-excitation and thus, renders the above spectral observation. Further, the R-light excitation may originate from the surface states on the CIS lattice surface, whose DoS does not depend on the sample thickness significantly, whereas the G-/B-light excitation comes from the transition between the energy bands with the DoS drops in thinner samples. Based on the existing experimental results a CIS thickness of 10 nm was selected, because of the corresponding dominating R-light response as well as the reasonable extension to the B-region.

Once the material candidates are determined, the fabrication of prototype stacking color sensor empowered by these vdW-Ss can proceed. FIG. 2D illustrates an example of the device fabrication workflow. To this end, the method of mechanical exfoliation can be employed to isolate these vdW-Ss with proper thicknesses from the bulk crystals shown in FIG. 1B and they can be dry transferred to construct the prototype vertical color sensor in a bottom-up manner illustrated in FIG. 2D. On the bottom of the entire stacking structure, a R-channel layer (e.g., a CIS layer of 10 nm) is formed (212) to serve as the R-sensing channel with electrodes patterned (215) by, e.g., a direct laser writing system or other appropriate method. Then, a first insulating layer is introduced over the R-channel layer and electrodes (218) either by depositing or transferring dielectric materials such as, e.g., MgF₂ or mica or other insulating material such as, e.g., GaF₂, SiO₂, polymer thin film, etc. On the first insulating layer, the same procedure is repeated to establish a G-channel layer (218) (e.g., made of 13 nm InSe) as the G-sensing channel and electrodes patterned (221). A second insulating layer is then formed over the G-channel layer and the electrodes (224), followed by forming the B-channel layer (224) (e.g., fabricated with a 25 nm GaS layer) as the B-sensing channel and patterning electrodes (227). The electrodes can be transparent electrodes (e.g., metallic indium tin oxide). FIG. 2D also includes optical images of the stacking process and the resulting prototype device. Their scales are 5 μm, as shown by the solid white line in each image. In some implementations, the stacking structure can comprise a third insulating layer formed over the B-channel layer, followed by forming a UV-sensing channel (and patterning electrodes). In some cases, the stacking structure can comprise an IR-sensing channel (and electrodes) on the bottom, with an initial insulating layer over the IR-sensing channel upon which the R-channel layer can be formed.

Succeeding the fabrication, functional verification of the device was carried out. As introduced earlier, the fundamental principle of the newly designed color sensor is to detect the RGB light component individually on each sensing layer, leveraging the rich selection of vdW-Ss and their widely tunable energy band structures. As a demonstration of successful prototype fabrication, FIG. 2E shows the normalized photoresponse spectra (P.R.) of these RGB-channels (with a bias voltage of 1V) calculated with the equation of R(λ)=[I_{light}(λ)−I_{dark}]/P(λ) and multiplied by factors of 50.0, 1.0, and 53.4, respectively. By doing so, the areas enveloped by each of the spectral curves are equalized so that white light with a flat spectrum renders the same response levels from every channel. (i.e., the ratio among this is 1:1:1). This procedure is known as white-balance (WB) calibration, which is an important step towards accurate color sensing.

As a reference, a spectral chart is inserted underneath the photoresponse curves and clearly demonstrates that each sensing layer in the fabricated prototype successfully performs the designed function with the CIS primarily detecting the R-light; the InSe mainly responding to the G-color; and the GaS working in the B-region. More importantly, rational overlaps exist along with their respective maxima, as requested by the fundamental color sensing principle to promise accurate color recognition. The large magnification factor for CIS may be attributed to the relatively small sample area obtained in the exfoliation, as shown in FIG. 2D, whereas the large factor for GaS may be attributed to high electrode contact resistance, which is a common challenge for wide bandgap semiconductors, such as GaN.

Besides the spectral response, another prerequisite for color sensing is a linear dependence of photocurrent on incident light power in each sensing channel. The reason is that color measuring depends on the ratio among the photocurrent readings from these channels, other than their absolute values that represent the light brightness instead. Thus, excellent linearity in each channel can ensure a precise color measurement independent of the intensity. Otherwise, the detected light color can drift as the intensity changes. To evaluate the linearity of the prototype device, the photocurrent-power (I-P) dependence of the GaS, InSe, and CIS layers was measured respectively by shining 458 nm, 514 nm, and 647 nm lasers with adjustable brightness. FIG. 2F shows photocurrent-light intensity curves of each sensing channel measured with a bias voltage of 1V. The curves of CIS, InSe and GaS layers are multiplied with the spectral normalization factors of 50.0, 1.0, and 53.4, respectively.

FIG. 2F unveils that all the sensing channels in the device have linear I-P behaviors, meeting the color sensing prerequisite. The dark current and photocurrent I-V curves of the sensing channels CIS, InSe and GaS, respectively, were also tested, as exhibited in FIGS. 2G-2I. The GaS, InSe, and CIS layers were excited with 458 nm, 514 nm, and 647 nm lasers, respectively, with an intensity of 17.5 mW/cm². Very low and constant dark currents were confirmed in all sensing channels. Meanwhile, all photocurrents increase with a higher bias voltage, suggesting that a higher voltage in a reasonable range without saturating the sensing layers can enhance their sensitivity and detectivity. The insets show the detailed data about the dark current.

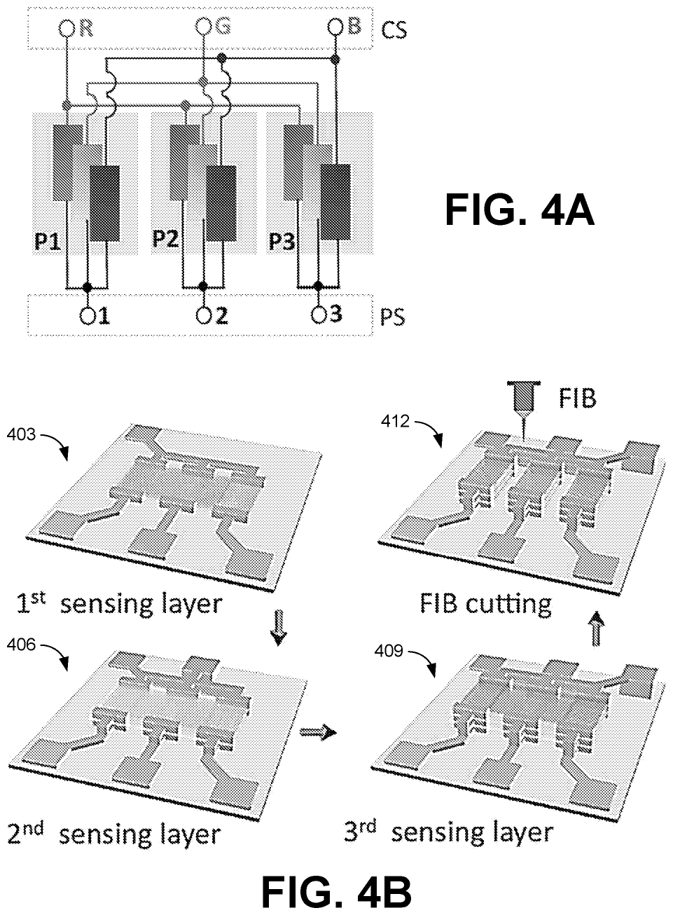

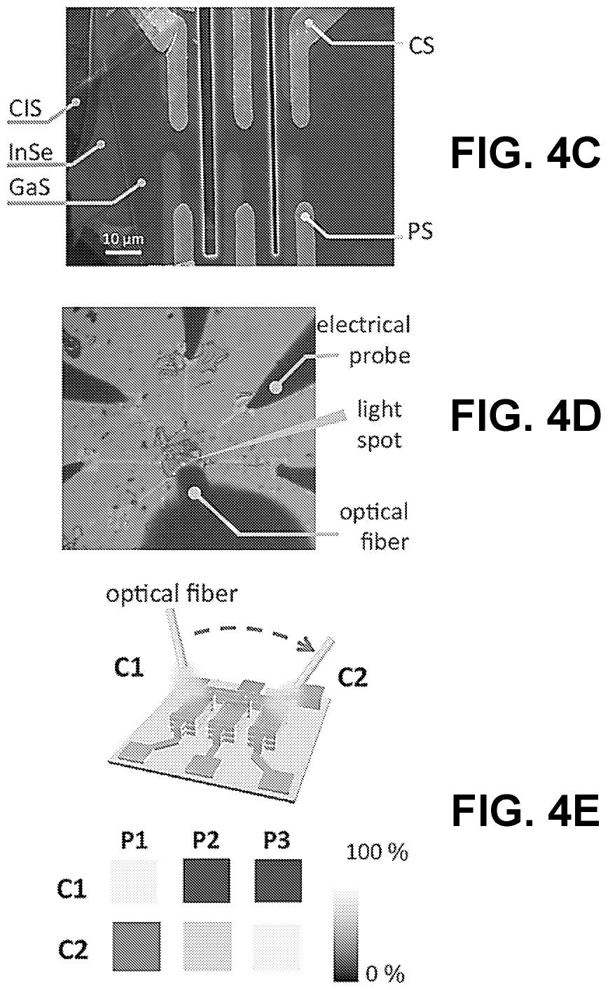

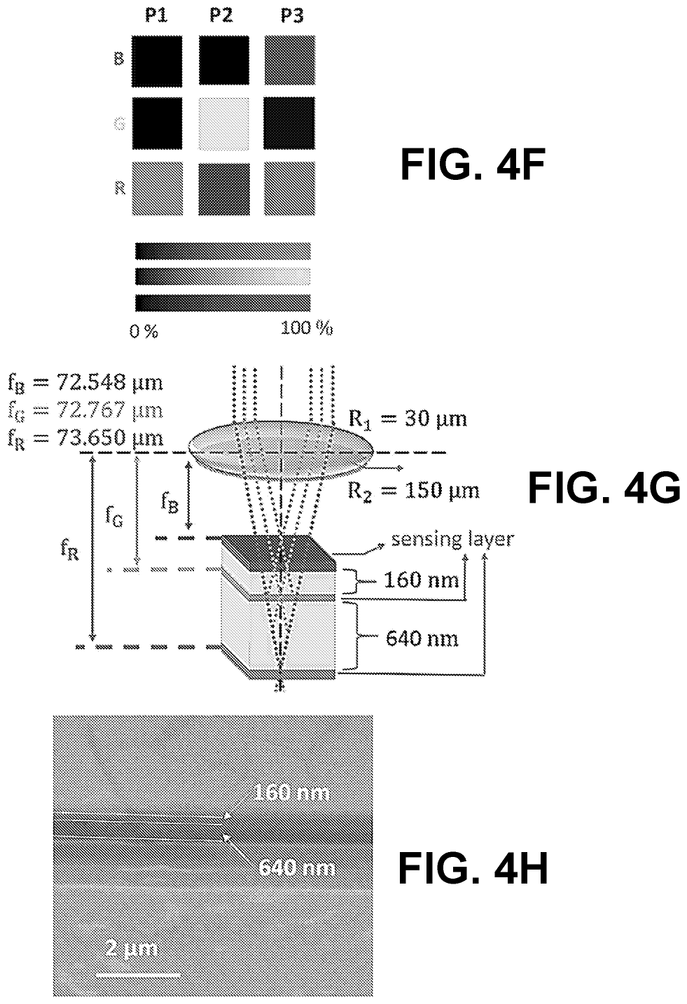

The above optoelectronic characterizations, particularly the photocurrent spectra and I-P measurement, ready the subsequent investigation of color sensing capability. As an example, the sensor was employed to probe the color temperature, which is a parameter used for many applications, such as the process control of metallurgy, star activity monitoring, and many more. In the experiment, the sensor was illuminated with a halogen lamp. FIG. 3A illustrates the experimental setup used for the color temperature measurement experiment. A Halogen lamp 303 with a variable power setting 306 was used to generate white light with different color temperatures. The vdW—S-based vertical color sensor 309 was placed near the lamp and connected to the source meter unit 312 via a switch box 315 to read the photocurrents from respective sensing channels. By adjusting the lamp power, the filament temperature can be tuned, which approximately equals the color temperature to be measured, because the incandescent tungsten wire is approximately a black-body radiator. The color measured by the prototype device 309 can be represented in the form of (R, G, B), i.e., the photocurrent reading from each sensing layer, as listed in the upper table of FIG. 3B. The upper table lists the RGB raw values sensed by our device under four different power setting points (S1-S4).

Similar to other color sensors, these values depend on the physical properties, particularly the photoresponse spectra of the device. Thus, transformation of the raw color value of (R, G, B) into a standardized and device-independent form for data exchange and processing is needed. The CIE 1931 XYZ color space is one of the most widely accepted color representing system for this purpose. To get the standard values in the CIE system, the raw color coordinate can first be projected into the CIE color values of (X, Y, Z), which are given by:

$$( \begin{matrix}X \\ Y \\ Z\end{matrix} ) = M \cdot ( \begin{matrix}R \\ G \\ B\end{matrix} ) . \qquad ( 1 )$$

Here, M is a 3x3 matrix named color correction matrix (CCM), whose determination includes several steps, including white-balance correction, color-space transformation, etc., and each step has its corresponding correction matrix denoted as M_{WB}, M_{CT}, and so forth. The resulting CCM can be expressed as M=M_{CT}×M_{WB}. Because the photoresponse spectra of the prototype sensor have distinct R, G, and B peaks and proper spectral overlap similar to the standard tristimulus curves, it may be hypothesized that M_{CT} is an identity matrix, so that M≈M_{WB}. For one example of a fabricated sensor, the CCM may be approximated by M_{WB}, where:

$${M}_{WB} = ( \begin{matrix}50. & 0 & 0 \\ 0 & 1. & 0 \\ 0 & 0 & 53.4\end{matrix} ) . \qquad ( 2 )$$

These matrix elements are the normalizing parameters that equalize the CIS, InSe, and GaS spectral areas in FIG. 2E, generating the corrected tristimulus values with the color correction matrix. Accordingly, the lower table of FIG. 3B shows the calculated XYZ values of the four power setting points (S1-S4). Although this is a primary approximation, it endowed the prototype sensor with a rational accuracy to sense the color.

Further, the three-dimensional (X, Y, Z) expression can be simplified into a two-dimensional form by using the formula of:

$$a = X / ( X + Y + Z ) , \qquad ( 3 )$$

$$b = Y / ( X + Y + Z ) , \qquad ( 4 )$$

which ignores the absolute light intensity because only the ratio among the coordinates instead of their absolute values represents the light color. These values of (a, b) are defined as the color coordinates in the two-dimensional CIE 1931 color space shown in FIG. 3C. The coordinates of the four power setting points are labeled as the white spots in FIG. 3C and indicate the corresponding color temperature of 2500 K, 2750 K, 3000 K, and 3400 K. The crosses denote the measured color coordinates of the laser lines at 647 nm, 514 nm, and 458 nm.

To examine the accuracy, the color temperatures of 2650 K, 2830 K, 2960 K, and 3250 K were also determined by fitting the emission spectra of these setting points with the black-body radiation curves. FIG. 3D shows the emission spectra of the halogen lamp with the four power setting points and the color temperatures obtained by spectral fitting with the black-body radiation curves (dash line 321). Because a silicon photodetector was employed for the spectrum collection, only the spectra in the UV to visible light range (400˜800 nm) were adopted for the fitting. Via comparison, a close matching between the datasets was obtained from the above two methods with an error within 5.0%, confirming the practical feasibility and measurement accuracy of the device architecture. Also note that the halogen lamp brightness increases with a higher power, as shown in the RGB values in FIG. 3B and the spectra in FIG. 3D. Nevertheless, the color temperature measurement was not affected by this variation, thanks to the excellent linear I-P relationship that eliminates the effect of absolute light intensity, as introduced earlier.

Following the same procedure, the color coordinates of laser lines of 647 nm, 514 nm, and 458 nm were measured, as shown in FIG. 3C. It was observed that the sensor also successfully distinguishes these colors, although some deviations exist between the measured and expected coordinates. This may be attributed to only including the WB correction in the process, whereas the introduction of M_{CT} can produce more precise measurements. But, the calibration of M_{CT} utilizes sophisticated but established procedures beyond the focus on demonstrating the fundamental principles and practical application potentials in this disclosure.

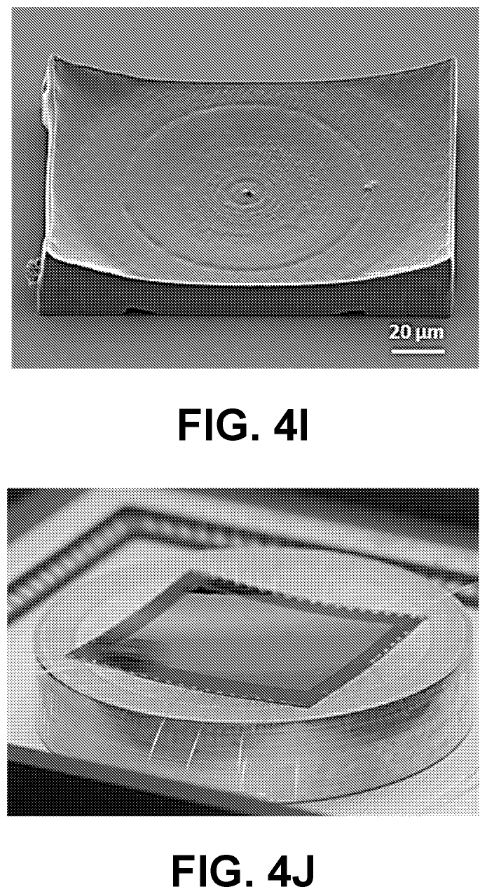

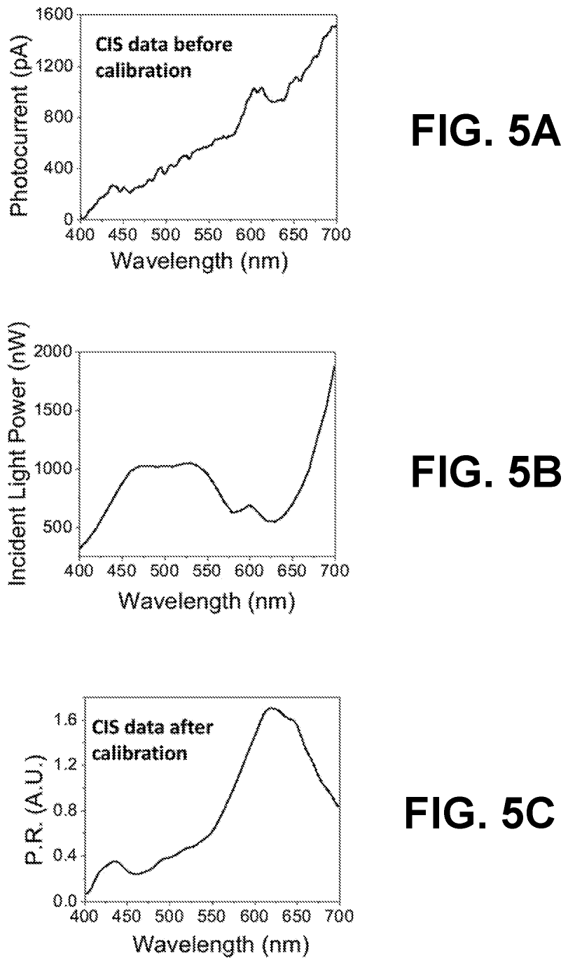

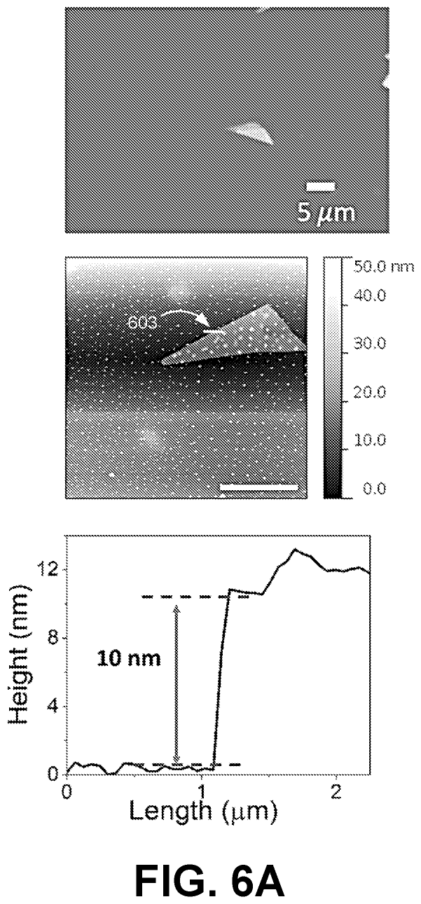

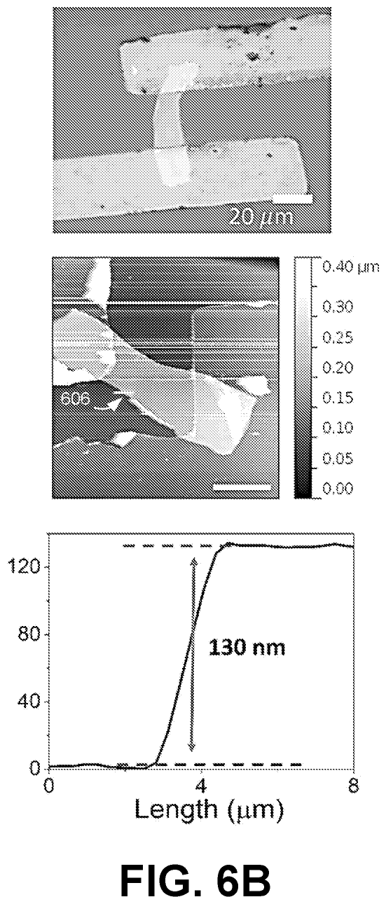

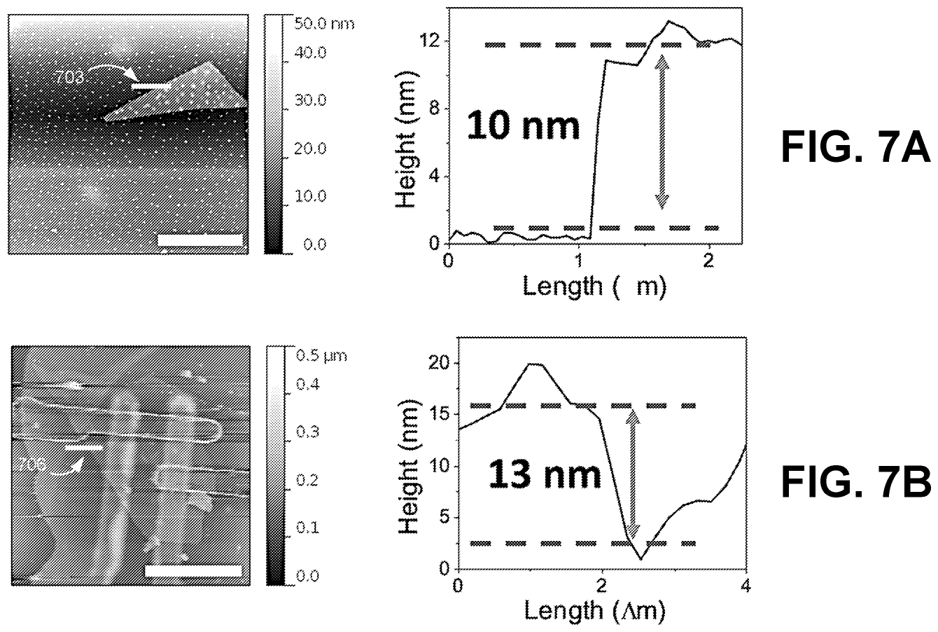

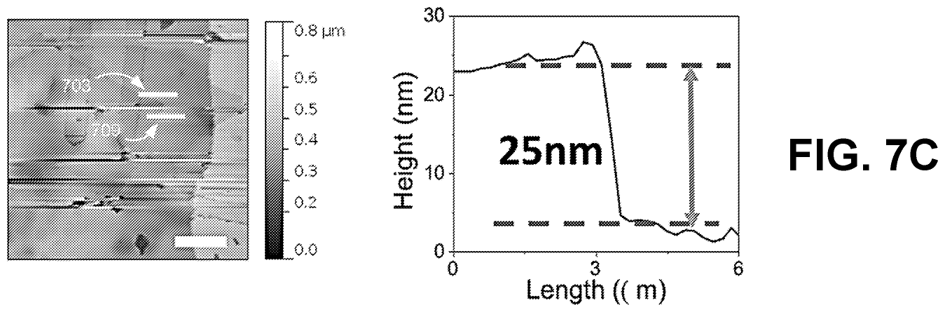

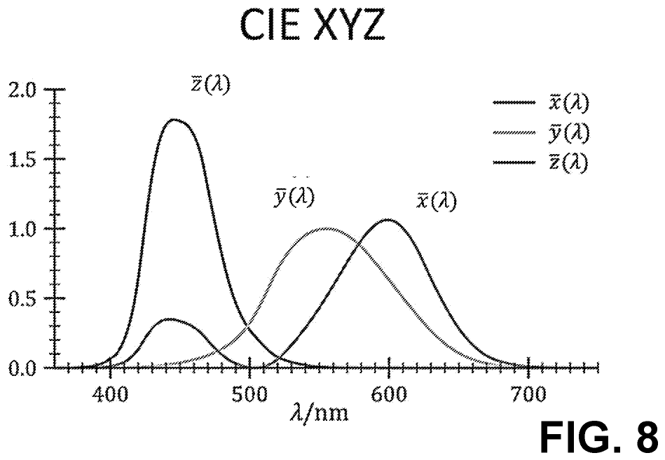

Besides working as a stand-alone unit for color recognition, the disclosed architecture can also be integrated into arrays or matrices serving as image sensors in cameras. Its compact design and excellent optoelectronic performance open a new pathway towards the downscaling of image sensors and cameras for biology and environmental applications, particularly following the trend of micro-robotic techniques. Therefore, instead of being satisfied with the single unit prototype, exploration of the scalable fabrication potential was continued, including the chromatic aberration correction configuration which has rarely been achieved in preceding image sensors. To this end, a three-pixel color sensor array was designed with the circuit diagram shown in FIG. 4A. The color sensor includes a total of nine photodetectors with each one of them having two electrodes as shown in the FIG. 4A.

The “top” electrodes of different pixels were connected, but the same channels connected together to obtain the channel selection (CS) terminals. All three “bottom” electrodes in the same pixel are bundled to form the pixel selection (PS) terminals. In this manner, each channel and each pixel can be individually controlled through the arbitrary combination of each CS and PS terminal. FIG. 4B illustrates the workflow for the construction of the three-pixel sensor array with a similar transfer and stacking procedure introduced with respect to FIG. 2D. At 403, the R-channel sensing layer (e.g., a CIS layer of 10 nm) is formed and the electrodes patterned. Next at 406, a first insulating layer (e.g., MgF₂ or mica or other insulating material such as, e.g., GaF₂, SiO₂, polymer thin film, etc.) is disposed over the R-sensing channel and electrodes, and the G-channel sensing layer (e.g., a InSe layer of 13 nm) is formed on the first insulating layer and the electrodes patterned. At 409, a second insulating layer is formed over the G-channel sensing layer and electrodes, followed by forming the B-channel sensing layer (e.g., a GaS layer of 25 nm) and patterning the electrodes. The insulating layers (e.g., MgF₂ thin films, mica or other insulating material such as, e.g., GaF₂, SiO₂, polymer thin film, etc.) can be thermally deposited between the neighboring sensing channels with the thickness controlled during the thermal deposition process. Following these steps, the monolithic structure can be cut into three independent pixels by, e.g., a focused ion beam (FIB) at 412, delivering the as-designed three-pixel color sensor array with its fake-color scanning electron microscopic (SEM) image exhibited in FIG. 4C.

After the fabrication, two device functionality tests were performed on the device, including spatial resolving of light intensity distribution and color recognition. The spatial resolving test was conducted on a probe-station and incident light coupled onto the device proximately through an optical fiber with a diameter of 20 μm. The optical fiber has a similar size to the pixels and its position was controlled by a micro-manipulator that enables individual pixels to be predominately illuminated. FIG. 4D shows the optical microscopic image of the experimental setup configured for the spatial resolved light intensity mapping and color sensing, including the device under investigation, electrical probes, and optical fiber. Electrical probes are connected to the sensor array through the CS and PS terminals. And a 20 μm optical fiber can selectively illuminates the pixels in the array. The glowing spot in the picture is the light projected by the fiber tip to illuminate an area of the sample. By moving the optical fiber position across the array, the photocurrent mapping (from the G-channel) were obtained.

FIG. 4E illustrates an example of the detected light intensity distribution. The three-pixel array was illuminated with two optical fiber alignment configurations (C1 and C2) shown in the upper panel. The lower panel shows the photoresponse of these pixels in greyscale, which is normalized by setting the highest photocurrent reading at 80% and zero at 0%. The results verify that the array can detect the spatial distribution of light intensity. Additionally, R-, G-, and B-light was coupled to the first, second, and third pixel, respectively, to examine their color recognition capability. FIG. 4F shows the responses from these pixels from the RGB light color recognition test on the three-pixel color sensor array in the form of colored grayscale. The R-, G-, and B-light were coupled to the first, second, and third pixel respectively, and the corresponding responses multiplied by the WB factors (50.0 for R-channel, 1.0 for G-channel, and 53.4 for B-channel) are shown in the colored greyscale, which sets the high photocurrent reading as 100%, and zero at 0%. Every pixel correctly recognized the color of the light projected on it, proving that they all have the full-color sensing capability. The successful demonstration of the spatially resolved color recognition capability showcases the applicability of the device architecture for ultra-compact image sensors through a large-scale integration of multiple pixels.

The vertical device architecture can also fundamentally address the problem of intrinsic chromatic aberration rendered by an optical lens. During the device fabrication the thicknesses of the insulating layers, such as thermally deposited MgF₂, mica or other insulating material such as, e.g., GaF₂, SiO₂, polymer thin film, etc., between the neighboring color sensing layers can be precisely controlled. In such a way, the focus points of R-, G-, and B-light can be aligned to the corresponding sensing layers to correct the chromatic aberration that is intrinsically attributed to a single lens. This can also be applied to insulating layers between IR and UV sensing layers and the color sensing layers. FIG. 4G schematically illustrates the design principle of a vdW—S-based vertical color sensor for chromatic aberration correction. For a model single BK7 bi-convex lens with surface radii of 30 μm and 150 μm, the focal lengths of the R-, G-, and B-light can be calculated as 73.650 nm, 72.767 nm, and 72.548 nm, respectively. Accordingly, MgF₂ insulating layers of 640 nm and 160 nm are formed between the sensing layers to correct the chromatic aberration. With this structure, it is unnecessary to employ glued lenses composed of elements with both negative and positive refraction indexes to correct the chromatic aberration. The simplified lens design, in turn, facilitates a more compact camera design.

As an example, the chromatic aberration of a BK7 lens with the radii R₁ of 30 μm and R₂ of 150 μm was calculated, according to the equation

$$\frac{1}{f} = ( n - 1 ) \cdot ( \frac{1}{{R}_{1}} - \frac{1}{{R}_{2}} ) ,$$

and focal lengths of 72.548 μm, 72.767 μm, and 73.650 μm were found for the B-, G-, and R-light, respectively. Accordingly, a device was fabricated with a MgF₂ insulating layer of 160 nm between the GaS and InSe sensing layers and a MgF₂ insulating layer of 640 nm between the InSe and CIS layers. FIG. 4H is an SEM inspection image of the cross-section of the fabricated vertical color sensor. These fabrication parameters can be adjusted according to the design of the lens. Note that since the vdW-Ss naturally have excellent mechanical flexibility, the image sensor can obtain a random geometry to compensate for the field curvature. This principle also applies to the full-color image sensors based on the vertical vdW-S architecture.

Since the entire device structure is flexible, a curved sensor can be obtained with a curvature radius down to micrometers, whereas the conventional silicon-based sensor can only reach millimeter-scale bending. The micro-scale bending can be achieved by forming the finished flexible sensor on a prefabricated curved sensor holder such as the example shown in FIG. 4I. The geometry of the sensing device can be used to compensate for the field curvature generated by an optical lens that directs the light into the device. The insulating layer thickness can be changed to compensate for the chromatic aberration generated by the lens system. The field curvature correction, which is implemented by flexible semiconductor, can be made using the curved sensor holder. The sensor holder can be fabricated with a fixed curvature degree using, e.g., micro-3D printing. FIG. 4J shows an example of a fabricated color sensor on a curved holder. The fabricated color sensor can be detached from the holder, with the color sensor matching the curvature degree by itself because of its flexibility.

In summary, a prototype color sensor empowered by vertically stacked vdW-Ss has been successfully demonstrated. Leveraging the broad selection and wide tunability of the vdW-S energy band structures, excellent photoresponse was implemented from a stacking sensor composed of CIS, InSe, and GaS to sense the three primary colors of R, G, and B, respectively. After calibration, this structure can effectively recognize the color of light and output the corresponding color coordinate in the CIE 1931 color space. The optoelectronic characterization and color sensing experiments all confirmed the feasibility and effectiveness of this design with a compact volume and without compromising the device performance. Furthermore, a method for the scalable fabrication of the vertical stacking architecture into a pixel array was also illustrated with the capability of chromatic aberration correction. The as-demonstrated sensor array not only has a compact vertical structure by itself, but it also facilitates the simplification of optical lens systems. As such, the sensor architecture can give rise to elegant solutions to the comprehensive miniaturization and improvement of cameras for biological, medical, and environmental applications among others.

### Methods

Material Synthesis. CIS and InSe were synthesized according to “Ternary CuIn₇Se₁₁: towards ultra-thin layered photodetectors and photovoltaic devices” by S. Lei et al. (Adv. Mater., 26, 7666-7672, 2014) and “Evolution of the electronic band structure and efficient photo-detection in atomic layers of InSe” by S. Lei et al. (ACS Nano, 8, 1263-1272 (2014). A GaS single crystal was grown using stoichiometric quantities of gallium and sulfur from sigma Aldrich (purity <99.99). To perform GaS crystal growth, a tube furnace was used with two zones and kept at temperature 950° C. and 450° C. for 24 hours. The gallium was located in the 950° C. zone. Then, the tube followed a natural cooling until reaching room temperature.

Sample Preparation. The exfoliation of vdW-S on the silicon dioxide was done using blue tape (Nitto SPV224PR-MJ). Similarly, the insulation layer material mica on polydimethylsiloxane (PDMS) film (Gel Pak Gel Film PF-30-X4) was exfoliated, which acted as the transfer medium. By employing the dry-transfer method, mica was transferred on the top of the first layer vdW-S with a home-build dry transfer workflow. The target substrate was located at the bottom fixed stage which could be heated, and the new flake on PDMS which needed to be transferred was stuck on the top transparent glass stage, the XYZ knobs of the top glass stage could control its movement. The top flake and bottom substrate can align with each other under a microscope. After alignment, the top glass stage was lowered down until it touched the substrate. In order to make them fully touching and increase the transfer success rate, a heat treatment was performed for the target substrate at 90° C. for 3 minutes. After finishing the transfer, the heating was stopped first and the top glass stage gently lifted in case of any unexpected tearing under a quick elevating. The same procedures were done for every transfer process including other topper insulating layers and vdW-S flakes in this study.

Material Characterization. The AFM study was performed on the Veeco MultiMode V AFM system under tapping mode. The photoresponsivity spectra were captured with the collaboration of a source meter unit (e.g., SMU, Keithley 2450), a low-noise current preamplifier (e.g., Stanford Research System SR570), an oscilloscope (e.g., Tektronix TBS 2000 Series Digital Oscilloscope). I-V and I-P characteristic curves of RGB components of the color sensor were measured on the home-build high vacuum probe station, with the Keithley 2634B SMU. A Bio-Rad argon-krypton ion laser, and a Lexel 85 argon-ion laser were employed to generate the 458 nm, 514 nm, and 647 nm excitation. The intensity was controlled by two polarizers in series.

Device Fabrication. For all device fabrication in this study, a home-built direct laser writing system with 450 nm diode laser was used to fabricate electrodes on each color sensing layer for optoelectronic testing. After exfoliation and transferring of each color sensing layer, followed by the spin-coating 100 nm undercut resist (e.g., Kayaku Advanced Material PMGI SF 3S) and 300 nm KL5305 photoresist (e.g., Kem Lab KL5305 HR). After finishing the exposure, the patterns were obtained by soaking in the KL5305 matching developer (e.g., Kem Lab TMAH Developer 0.26N) for 30s. Next, the thermal evaporation (Ti 5 nm/Au 45 nm) and metal lift-off procedures were done to complete the device fabrication.

Focus Ion Beam Milling. The FIB milling on the three-pixel array was performed on Hitachi NB5000 nanoDUE'T FIB-SEM system, in which 40 kV Ga-ion beam was used for FIB cutting. The cross-section of the chromatic aberration correction structure was cut on a Raith Velion focus ion beam lithography system. The Raith Velion system offers a dedicated 35 kV nano-FIB column for directing, Ga-free, two beams (either Si with a 16.7 nm minimum feature size or Au with a 18.6 nm minimum feature size) nanofabrication with a nanometer scale placement accuracy and reliability due to a laser interferometer stage utilization. In the study, Au⁺⁺ focused ion beam yielded better results than Si⁺⁺ focused beam in the milling of CIS, InSe, GaS, and MgF₂ stacks.

Scanning Electron Microscopy. All SEM images were captured on the Tescan Vega3 system.

Spectra collection on halogen lamp. An Andor 500R spectrometer equipped with an iDus 420 TE cooled CCD camera was used to capture the radiation spectra of the halogen lamp. The CCD camera was cooled to −40° C.

Photoresponsivity spectrum calibration process. The spectrum calibration facilitates obtaining accurate photoresponse results. In order to achieve that, the impact of incident light power of the monochromatic light source is considered. Here, CIS is taken as an example, and the specific calibration steps in this study are described as follows:
FIG. 5A shows the original photoresponsivity spectrum of the CIS layer by extracting the dark current, i.e., (I_{light}−I_{dark}), versus the wavelength before calibration. It exhibits a continuous increase from 400 nm to 700 nm. It is difficult to find the correct and accurate response peak.
FIG. 5B is the spectrum of monochromatic light source in terms of incident light power, as a function of wavelength, P(λ).
The calibration requests the absolute photoresponsivity as a function of wavelength R(λ) which can be calculated with the equation of R(λ)=(I_{light}−I_{dark})/P(λ). FIG. 5C shows the photoresponsivity spectrum of CIS after calibration. It shows a strong response in the red light band from 550 nm to 700 nm. By doing so, the correct spectrum will be shown, and the specific response peak position is also clear. The same photoresponsivity spectrum calibration process also applies to the InSe and GaS sensing layers.

CIS thickness-dependent photoresponsivity spectra evolution. To obtain the proper material candidate for red sensing, the relationship between the material thickness and the evolution of photoresponse spectral was explored. A series of CIS samples with various thicknesses were exfoliated and their photoresponse spectra were collected. Examples of the optical pictures and AFM data of two devices are shown in FIGS. 6A and 6B. In FIG. 6A, the top panel is the CIS optical image in this vdW—S-based vertical color sensor, the middle panel and lower panel show both the AFM mapping and the thickness profile of it, which confirmed a thickness of 10 nm. The scale of the AFM mapping image is 5 μm and the profile measurement was performed along the line 603 in AFM mapping image. CIS with this thickness exhibits a strong response from 550 nm to 700 nm in the red light wavelength range.

In FIG. 6B, the top panel is another CIS sample's optical image, the middle panel and lower panel also show AFM mapping and thickness profile of it, which confirmed a thickness of 130 nm. The scale of AFM mapping image is 20 μm and the profile measurement was performed along line 606 in the AFM mapping image. By comparing these three devices, it can be seen that the photoresponse spectra of CIS for short wavelengths range (400 nm to 550 nm) are more sensitive to the thicker samples, and the increased thickness leads to a flat response covering the entire visible wavelength range. This trend helps determine that thinner CIS will be the proper candidate material for red color sensing because its strong photoresponsivity in this range.

Atomic force microscope (AFM) images of vdW—S-based vertical color sensor, the dry transfer and stacking device fabrication procedures. The thickness of each sensing material in this vdW—S-based vertical color sensor will control its photoresponsivity to the corresponding color which leads to an impact on the sensing capability. Here, we use atomic force microscope to characterize the red, green and blue sensing layers' thicknesses. FIGS. 7A-7C show AFM images of the CIS (R-channel), InSe (G-channel) and GaS (B-channel) layers in the study, with thicknesses of 10 nm, 13 nm and 25 nm, respectively. This thickness ensures that the respective response intervals on the spectrum coincide with the red, green and blue wavelength ranges, further confirming the feasibility of the color sensing function of the device. The left panels show the AFM mapping images and the right panels show the thickness profile. The scale of the AFM mapping image of FIG. 7A is 5 μm and the profile measurement was performed along line 703 in the AFM mapping image. The scale of AFM mapping image of FIG. 7B is 20 μm and the profile measurement was performed along line 706 in the AFM mapping image. The scale of the AFM mapping image of FIG. 7C is 20 μm and the profile measurement was performed along line 709 in the AFM mapping image.

Regarding to the fabrication stacking, a relatively clean dry-transfer method was chosen to avoid contamination of chemical reagents. A home-built platform was employed to finish dry-transfer and stack all layers including sensing layers and insulating layers. The entire platform comprises two parts: an upper part which includes a transparent slide glass for placing the material to be transferred and a lower part designed to hold the target substrate. It is fixed on a micro-controller that can be adjusted in XYZ direction, and contains a heating stage that can be rotated. The XYZ direction adjustment and rotation functions help find the best stacking position and angle during the transfer process. Meanwhile, the heating function can further improve the success rate of the transfer by providing adhesion between layers. However, the heating temperature varies with the material to be transferred and its thickness with the basic trend that as the thickness increases, a higher temperature or longer heating time is needed.

Color matching function. Any color in nature can be obtained by mixing the three basic elements of R, G and B in different proportions. Therefore, these three RGB color standards can play a key role in the perception and accurate reproduction of all other colors. In the late 1920s, a series of color matching experiments was initiated to perform such quantification which is also used by the International Commission on Illumination (CIE) to present the CIE color space standards. The experiment projected the tested light and the standard light that is a mixture of three basic elements (RGB) on the same screen and compared these two until they were regarded as the same color while the observer cannot distinguish the difference between them by changing the composition ratio of three elements in standard light. The red, green, and blue mixing ratios of the latter were recorded for the standard values for reproduction the former color. By testing a large amount of monochromatic light, the color matching data was obtained. On this basis, CIE further proposed the concept of XYZ color space by applying a color correction matrix to correct the RGB color values obtained from the aforementioned experiment, hence, a three component CIE XYZ color matching function was gained, as shown in FIG. 8, which is also the international color standard values that is widely used. From this graph, the standard R, G and B components of any wavelength in the visible light range can be read directly.

Other than the regular RGB color image sensor, the functionality of the stacked multiple layer design can be expanded. For example, the device functionality can be extended to on-chip spectrometers, and cameras with spectral analysis function for medical diagnosis, drug identification, and material analysis. In such cameras, each pixel can provide the capability of spectral analysis. Current on-chip spectrometers involve light dispersing mechanisms, such as micro-grating, filter array, disordered photonic structures, and a linear variable band-pass filter, which can impede the further downscaling of the system.

By stacking multiple layers of vdW-S with continuously varying photoresponse spectral range, an alternate solution can be provided. For this purpose, layered vdW—S alloys can be employed instead of pristine compounds to continuously tune the bandgap, allowing the desired photoresponse characteristics to be obtained. For example, vdW-Ss such as GaSeS, InGaSe, InGaSeTe, InTe, InSe, GaSe, GaS, GaTe, InCuSe, MoS₂, MoSe₂, MoTe₂, WS₂, WSe₂, WTe₂, NbSe₂, TiS₂, or other vdW—S alloys can be used.

As one example, consider a group of GaSe₁₋ₓSₓ alloys with gradually opening bandgap. In this case, cut-off wavelengths can be blue shifted as the sulfur ratio (x) increases. Other examples can include, but are not limited to, InGa₁₋ₓSeₓ, InGa₁₋ₓSeₓTe, TexSe₁₋ₓ, GaₓIn₁₋ₓSe, GaSₓSe₁₋ₓ, MoSₓSe₁₋ₓ, MoₓW₁₋ₓSe₂, etc. FIG. 9A illustrates examples of commercial low-pass filters (top row) and synthesized GaSeS alloy samples (bottom row). The similarity in color variation clearly indicated a successful bandgap tuning of the synthesized samples.

A spectrometer-per-pixel (SPP) device can be fabricated using the vdW—S alloys with varying bandgaps as described. It works in such a way that each layer can provide two functions, serving as a photosensor detecting photons with energies higher than the bandgap while simultaneously acting as a low-pass filter to selectively release low-energy photons to the subsequence levels. FIG. 9B illustrates an example of a single-pixel spectrometer comprising layers that provide the two-fold functionality. Besides sensing the respective wavelength range, each layer also serves as low-pass filter for the subsequential layers. As shown, each layer detects photons allowing the lower energy photons to pass through to the next layer.

A camera comprising a SPP matrix has the same size as a regular camera, while offering full spectral analysis functionality without additional optical elements. As such, it can be applied to a wide range of applications including, e.g., endoscopy, medical imaging, cancer diagnosis, and other fields that would benefit from both image capturing and optical spectroscopy capabilities.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

The term “substantially” is meant to permit deviations from the descriptive term that don't negatively impact the intended purpose. Descriptive terms are implicitly understood to be modified by the word substantially, even if the term is not explicitly modified by the word substantially.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. The term “about” can include traditional rounding according to significant figures of numerical values. In addition, the phrase “about ‘x’ to ‘y’” includes “about ‘x’ to about ‘y’”.

1. A vertical color sensing element, comprising:
a R-sensing channel layer comprising a first sensing material;
a first transparent insulating layer disposed on a side of the R-sensing channel layer, the first transparent insulating layer having a first thickness;
a G-sensing channel layer comprising a second sensing material, the G-sensing channel layer disposed on a side of the first insulating transparent layer opposite the R-sensing channel layer;
a second transparent insulating layer disposed on a side of the G-sensing channel layer opposite the first transparent insulating layer, the second transparent insulation layer having a second thickness; and
a B-sensing channel layer comprising a third sensing material, the B-sensing channel layer disposed on a side of the second transparent insulating layer opposite the G-sensing channel layer.

2. The vertical color sensing element of claim 1, wherein the first and second thicknesses are based upon focal lengths of R-light, G-light and B-light entering the vertical color sensing device.

3. The vertical color sensing element of claim 2, wherein the focal lengths are associated with a lens directing the R-light, G-light and B-light into the vertical color sensing device.

4. The vertical color sensing element of claim 3, wherein the vertical color sensing element has a geometry conforming to a field curvature generated by the lens.

5. The vertical color sensing element of claim 3, further comprising a UV-sensing layer or an IR-sensing layer.

6. The vertical color sensing element of claim 5, wherein the UV-sensing layer is separated from the B-sensing channel layer by another transparent insulating layer, or the IR-sensing layer is separated from the R-sensing channel layer by another transparent insulating layer.

7. (canceled)

8. The vertical color sensing element of claim 1, wherein one or more of the first, second and third sensing materials are van der Waal semiconductors (vdW-Ss).

9. The vertical color sensing element of claim 1, wherein thickness of the first, second or third sensing material is based upon sensitivity of that sensing material.

10. The vertical color sensing element of claim 1, wherein the first sensing material comprises copper indium selenide (CIS), or the second sensing material comprises indium selenide (InSe), or the third sensing material comprises gallium sulfide (GaS).

11-12. (canceled)

13. The vertical color sensing element of claim 1, wherein the first transparent insulating layer comprises magnesium fluoride (MgF₂) or mica, or the second transparent insulating layer comprises magnesium fluoride (MgF₂) or mica.

14. (canceled)

15. The vertical color sensing element of claim 1, wherein the first, second and third sensing materials comprise a series of a van der Waal semiconductor (vdW-S).

16. The vertical color sensing element of claim 15, wherein the vdW-S is GaSe₁₋ₓSₓ, InGa₁₋ₓSeₓ, InGa₁₋ₓSeₓTe, TexSe₁₋ₓ, GaₓIn₁₋ₓSe, GaSₓSe₁₋ₓ, MoSₓSe₁₋ₓ, or MoₓW₁₋ₓSe₂, where 0≤x≤1 with each of the first, second and third sensing materials tuned to a different bandgap.

17. A vertical sensing device comprising an array of vertical color sensing elements of claim 1.

18. The vertical sensing device of claim 17, wherein the array of vertical color sensing elements is formed on a curved device holder.

19. The vertical sensing device of claim 18, wherein curvature of the curved device holder conforms to a field curvature generated by a lens that directs light into the array of vertical color sensing elements.

20. (canceled)

21. A vertical optical sensor, comprising:
a first sensing channel layer comprising a first sensing material comprising a van der Waal semiconductor (vdW-S);
a transparent insulating layer disposed on a side of the first sensing channel layer, the first transparent insulating layer having a thickness; and
a second sensing channel layer comprising a second sensing material, the second sensing channel layer disposed on a side of the insulating transparent layer opposite the first sensing channel layer.

22. The vertical optical sensor of claim 21, wherein the first sensing material exhibits a first photoresponse spectral range and the second sensing material exhibits a second photoresponse spectral range different than the first photoresponse spectral range.

23. The vertical optical sensor of claim 21, wherein the second sensing channel is a UV-sensing layer or an IR-sensing layer.

24. The vertical optical sensor of claim 21, wherein the vdW-S is a III-VI group semiconductor, a III-V group compound, or a transition metal chalcogenide.

25. The vertical optical sensor of claim 21, wherein the first sensing material comprises a vdW—S alloy having a first composition of elements tuned to a first bandgap and the second sensing material comprises the vdW—S alloy having a second composition of elements tuned to a second bandgap.

26. The vertical optical sensor of claim 25, wherein the vdW—S alloy is GaSe₁₋ₓSₓ, InGa₁₋ₓSeₓ, InGa₁₋ₓSeₓTe, TeₓSe₁₋ₓ, GaₓIn₁₋ₓSe, GaSₓSe₁₋ₓ, MoSₓSe₁₋ₓ, or MoₓW₁₋ₓSe₂, where 0≤x≤1 with each of the first and second sensing materials tuned to different bandgaps.

27-28. (canceled)
